(19) United States
(12) Patent Application Publication
(10) Pub. No.: US 2025/0259965 A1
(43) Pub. Date: Aug. 14, 2025

(54) INTERCONNECTING A PRINTED-CIRCUIT-BOARD SUBSTRATE TO ANOTHER SUBSTRATE OR TO A DIE

(71) Applicant: Tektronix, Inc., Beaverton, OR (US)

(72) Inventors: Forest E. Kernan, Portland, OR (US); Ghassan Abu-Hamdeh, Beaverton, OR (US); Matthew D. Borden, Beaverton, OR (US); Kevin Bain Cox, Portland, OR (US); Steven Tonthat, Beaverton, OR (US); Richard Jeffrey Smith, Donald, OR (US)

(21) Appl. No.: 18/971,820

(22) Filed: Dec. 6, 2024

Related U.S. Application Data
(60) Provisional application No. 63/553,080, filed on Feb. 13, 2024.

(51) Int. Cl. H01L 23/00

(52) U.S. Cl. CPC H01L 24/83; H01L 24/85; H01L 24/92; H01L 2224/83104; H01L 2224/83192; H01L 2224/83855; H01L 2224/8584; H01L 2224/92147

(57) ABSTRACT

A method of interconnecting a printed-circuit-board (PCB) substrate and an integrated-circuit (IC) die that includes dispensing epoxy into a die cavity of a PCB substrate, the die cavity having full-wrap edge-plating; positioning an IC die in the die cavity and substantially aligning a top surface of the IC die with a top surface of the PCB substrate; curing the dispensed epoxy; substantially filling a gap between the PCB substrate and the IC die with underfill; filling a remaining gap between the PCB substrate and the IC die with non-conductive, aerosol-printed material; curing the underfill and the non-conductive, aerosol-printed material; using additive manufacturing to dispense conductive traces at desired locations spanning the gap and interconnecting the PCB substrate and the IC die; and sintering the dispensed conductive traces. Related methods are also discussed.

### CROSS-REFERENCES TO RELATED APPLICATIONS

This disclosure is a non-provisional of and claims benefit from U.S. Provisional Application No. 63/553,080, titled “EXTREMELY HIGH BANDWIDTH INTERCONNECTS,” filed on Feb. 13, 2024, the disclosure of which is incorporated herein by reference in its entirety.

### TECHNICAL FIELD

This disclosure relates to test and measurement instruments, and more particularly to high bandwidth interconnect structures and methods for forming such structures.

### BACKGROUND

Test and measurement instruments, such as oscilloscopes for example, require ever-higher bandwidths in order to perform accurate measurement of ever-higher-speed signals in a device under test (DUT). Generally, test and measurement instruments receive an input signal to be measured from a DUT through an input connector, by way of either a cable or a probe connected between the DUT and the instrument. The input signal is then typically routed to a circuit that performs signal conditioning or other processing of the signal. Often, such signal conditioning or processing circuitry is embodied in a custom ASIC, for example.

Configurations of the disclosed technology address shortcomings in the prior art.

### BRIEF DESCRIPTION OF THE DRAWINGS

FIG. 1 illustrates a method of interconnecting a printed-circuit-board (PCB) substrate and an integrated-circuit (IC) die, according to an example configuration.

FIG. 2 is an isometric view of substrate-to-die interconnect using aerosol printing, according to an example configuration.

FIG. 3 is a detail view of a portion of the substrate-to-die interconnect of FIG. 2.

FIG. 4 is an exploded view of a portion of the substrate-to-die interconnect of FIG. 3.

FIGS. 5-7 are each partial exploded views of a portion of the substrate-to-die interconnect of FIG. 3, illustrating how some of the components are arranged.

FIG. 8 shows a portion of the substrate-to-die interconnect of FIG. 3, once the exploded components of FIGS. 4-7 have been positioned.

FIG. 9 illustrates a method of interconnecting printed-circuit-board (PCB) substrates, according to an example configuration.

FIG. 10 is an isometric view of substrate-to-substrate interconnect using aerosol printing, according to an example configuration.

FIG. 11 is an exploded view of a portion of the substrate-to-substrate interconnect of FIG. 10.

FIGS. 12-13 are each partial exploded views of a portion of the substrate-to-substrate interconnect of FIG. 10, illustrating how some of the components are arranged.

FIG. 14 shows a portion of the substrate-to-substrate interconnect of FIG. 10, once the exploded components of FIGS. 10-13 have been positioned.

FIG. 15 illustrates a method of interconnecting printed-circuit-board (PCB) substrates.

FIG. 16 is an isometric view of substrate-to-substrate interconnect using ribbon bonds, according to an example configuration.

FIG. 17 is an exploded view of a portion of the substrate-to-substrate interconnect of FIG. 16.

FIGS. 18-19 are each partial exploded views of a portion of the substrate-to-substrate interconnect of FIG. 16, illustrating how some of the components are arranged.

FIG. 20 shows a portion of the substrate-to-substrate interconnect of FIG. 16, once the exploded components of FIGS. 17-19 have been positioned.

### DETAILED DESCRIPTION

Configurations of the disclosed technology include interconnect structures that enable higher bandwidth test and measurement instruments, including bandwidths from DC to greater than 110 GHz, for example. Specifically, configurations provide robust, high-performance interconnects to get the input signal from the external customer-facing connector on the front of an instrument all the way to the inputs of a custom ASIC, for example. There are two major interconnect challenges in this path: 1) Connector to substrate and 2) substrate to ASIC.

For the first type of interconnect, connector to low loss substrate, challenges include that the interconnect should provide an electro-mechanically robust connection from the external facing connector to a low loss substrate material that supports fine metal feature requirements and ultimately a connection to an ASIC. Readily-made connectors that support 110 GHz cannot be attached directly to the types of low loss substrate materials required to make extremely high bandwidth anti-aliasing filters, attenuators, or support wirebond pitches to then connect to an ASIC. For example, all 1 mm connectors are designed to compression connect to PTFE-based or other organic low loss materials (that suffer water absorption which cannot be tolerated in an instrument) fabricated in the PCB process. The PCB process does not support the small line widths and tolerances required for filters or the pitch to wire or ribbon bond into the ASIC. Therefore, an interconnect has to be developed to allow a connector to be placed on a compliant material etched in the PCB process and then jump to a delicate material (like fused silica) to support filters, attenuators, etc., and bonding to the ASIC. Commercial high-speed applications typically do not need the demanding performance of an oscilloscope, so the losses incurred with off the shelf components are acceptable in those applications, but not for an oscilloscope.

For the second type of interconnect, low loss substrate to the ASIC, challenges include that ribbon bonds are typically used in RF and millimeter wave applications, but supporting bandwidths above 80 GHz breaks down for a variety of reasons. The ribbon bond inductance is high impedance over the lengths required. Parallel bonds that would reduce inductance require tighter pitches than the tools can support and not risk damaging and lifting the die pad metallization (not reliable and low yield). The die pad capacitance is low impedance over the sizes required. The length over which the combination of high and low impedance occur become large compared to the wavelengths above 80 GHz. There are matching techniques that make this easy to deal with in narrowband commercial applications but cannot be used for the broadband (DC-110 GHz) bandwidth required of a performance oscilloscope. The substrate materials that can support mode free (dispersion less) operation become limited. Alumina is commonly used at 70 GHz and below but at 110 GHz needs to be so thin (on the order of 2 mils thick) it becomes too difficult to handle without breaking.

Thus, interconnects according to configurations of the disclosure have three main objectives: (1) Reliability: Meet environmental operating conditions and mechanical stresses for a performance instrument; (2) Manufacturability: Manufacturable process and assembly methods free of on the bench manual tweaks and low yields; and (3) Stability: Consistent instrument measurement accuracy required over environmental operating conditions. Fluctuations in insertion loss over temperature and humidity have to be consistent and predictable. Does not exhibit small ground loop resonances (<0.5 dB) that appear, disappear, and shift in frequency over normal operating temperature and humidity changes. Also does not exhibit similar unacceptable changes brought about by forces applied to the connector. For example, the customer should not observe any change in measurements when the cable attached to the connector moves.

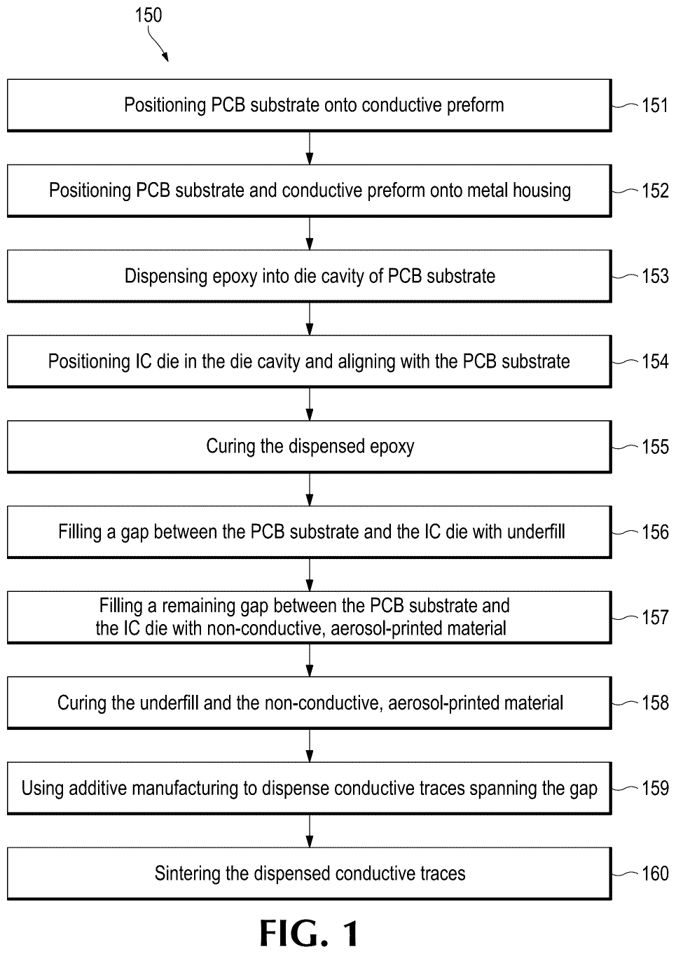

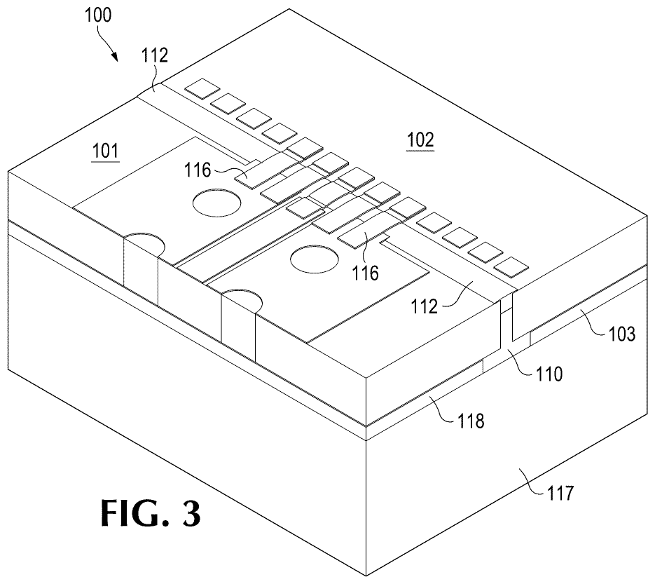

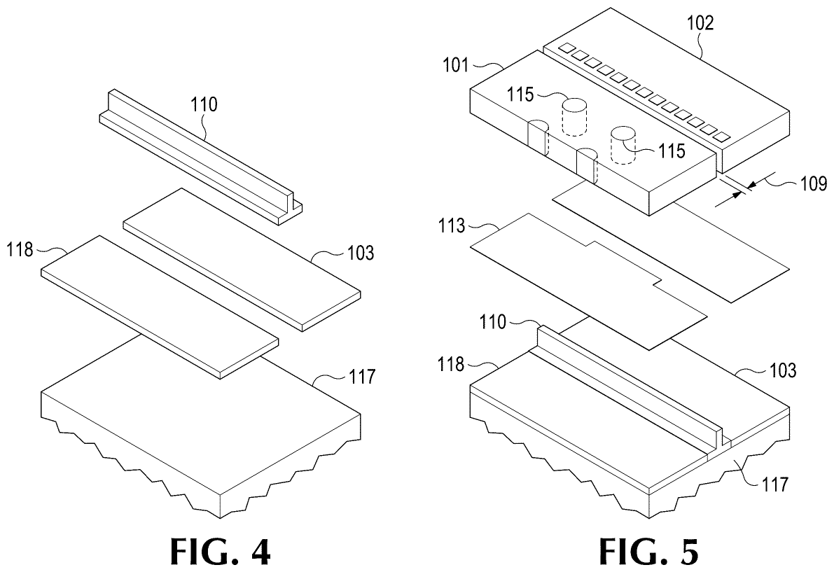

Accordingly, as illustrated in FIGS. 1-8, a method 150 of interconnecting a printed-circuit-board (PCB) substrate 101 and an integrated-circuit (IC) die 102 to provide an interconnected assembly 100 includes dispensing 153 epoxy 103 into a die cavity 104 of the PCB substrate 101. In configurations, the die cavity 104 may include one or more cutouts, or ears 105, that coincide with where a corner of the IC die 102 would be. Such ears 105 allow a needle tip to dispense the epoxy 103 between the IC die 102 and the PCB substrate 101. The die cavity 104 has full-wrap edge-plating 106. By “full wrap,” it is meant that the edge plating 106 extends between the grounds below the signal trace. In configurations, the full-wrap edge-plating 106 of the PCB substrate 101 enables extremely high bandwidth performance, meaning beyond 110 GHz. The method 150 of interconnecting the PCB substrate 101 and the IC die 102 also includes positioning 154 the IC die 102 in the die cavity 104 and substantially aligning a top surface 107 of the IC die 102 with a top surface 108 of the PCB substrate 101. As used in this context, “substantially aligned” means that the top surface 107 of the IC die 102 and the top surface 108 of the PCB substrate 101 are largely or essentially lying in the same plane without requiring perfect coplanarity, an example of which is illustrated in FIG. 8.

Once the IC die 102 is positioned in the die cavity 104, the method 150 of interconnecting the PCB substrate 101 and the IC die 102 also includes curing 155 the dispensed epoxy 103. The curing 155 may be, for example, snap (or rapid) curing.

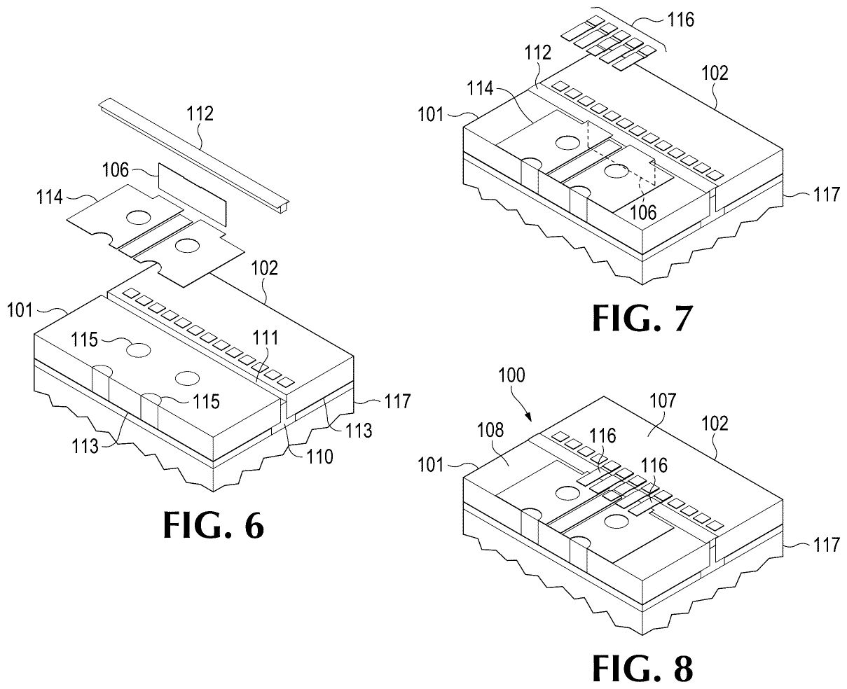

As illustrated in FIGS. 1-8, the method 150 of interconnecting the PCB substrate 101 and the IC die 102 also includes substantially filling 156 a gap 109 between the PCB substrate 101 and the IC die 102 with underfill 110. After substantially filling the gap 109, the underfill 110 is cured 158. As used in this context, “substantially filling” means largely occupying the gap 109 without actually occupying the entire gap 109. As illustrated, particularly in FIG. 6, while the underfill 110 substantially fills the gap 109, it does not entirely fill the gap 109. Instead, there is a remaining gap 111 between the PCB substrate 101 and the IC die 102, the remaining gap 111 being that portion of the gap 109 that is not filled with underfill 110. As a result, the method 150 of interconnecting the PCB substrate 101 and the IC die 102 also includes filling 157 the remaining gap 111 between the PCB substrate 101 and the IC die 102 with a non-conductive, aerosol-printed material 112. The non-conductive, aerosol-printed material 112 is printed in place in the remaining gap 111 rather than being printed elsewhere and then, once printed, positioned in the remaining gap 111. Once the non-conductive, aerosol-printed material 112 is placed, the method 150 of interconnecting the PCB substrate 101 and the IC die 102 also includes curing 158 the non-conductive, aerosol-printed material 112. The underfill 110 may be cured 158 before or after the non-conductive, aerosol-printed material 112 is placed.

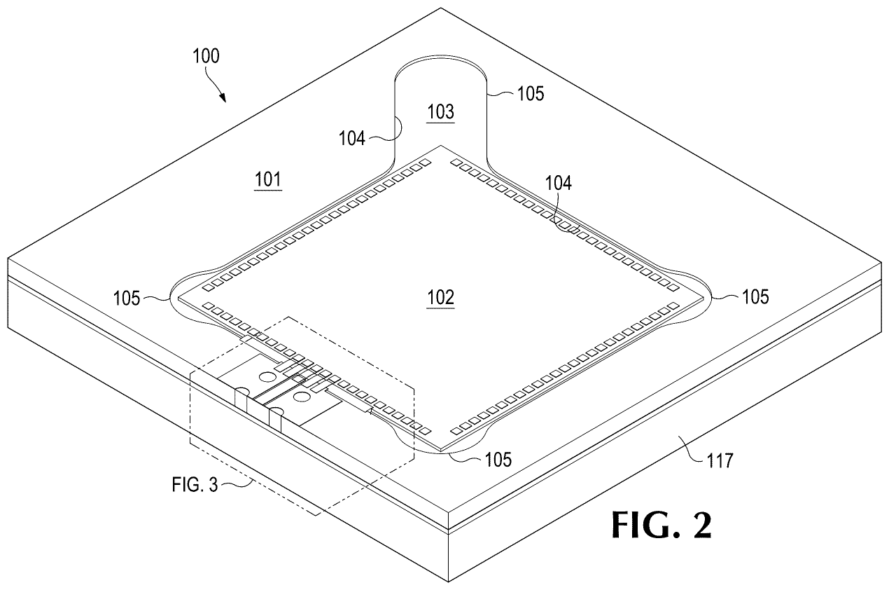

The term “PCB substrate 101” with regard to FIGS. 1-8 is intended to include the substrate bottom layer conductor 113 and the substrate top layer conductor 114, unless otherwise apparent from the context. FIGS. 2-8 also illustrate examples of plated vias 115 on the PCB substrate 101.

Next, the method 150 of interconnecting the PCB substrate 101 and the IC die 102 includes using 159 additive manufacturing to dispense conductive traces 116 at desired locations spanning the gap 109. The dispensed conductive traces 116 are dispensed in place at the desired locations spanning the gap 109 rather than being dispensed elsewhere and then positioned at the desired locations. The dispensed conductive traces 116 interconnect the PCB substrate 101 and the IC die 102. Then, the method 150 includes sintering 160 the dispensed conductive traces 116 to cure the dispensed conductive traces 116 and to improve the conductivity of the dispensed conductive traces 116.

In configurations, the method 150 of interconnecting the PCB substrate 101 and the IC die 102 may include positioning 151 the PCB substrate 101 onto a conductive preform 118 before substantially aligning 154 the top surface 107 of the IC die 102 with the top surface 108 of the PCB substrate 101. The conductive preform 118 may be, for example, a conductive epoxy preform. In such configurations, the method 150 may also include positioning 152 the PCB substrate 101 and the conductive preform 118 onto a metal housing 117 before substantially aligning 154 the top surface 107 of the IC die 102 with the top surface 108 of the PCB substrate 101.

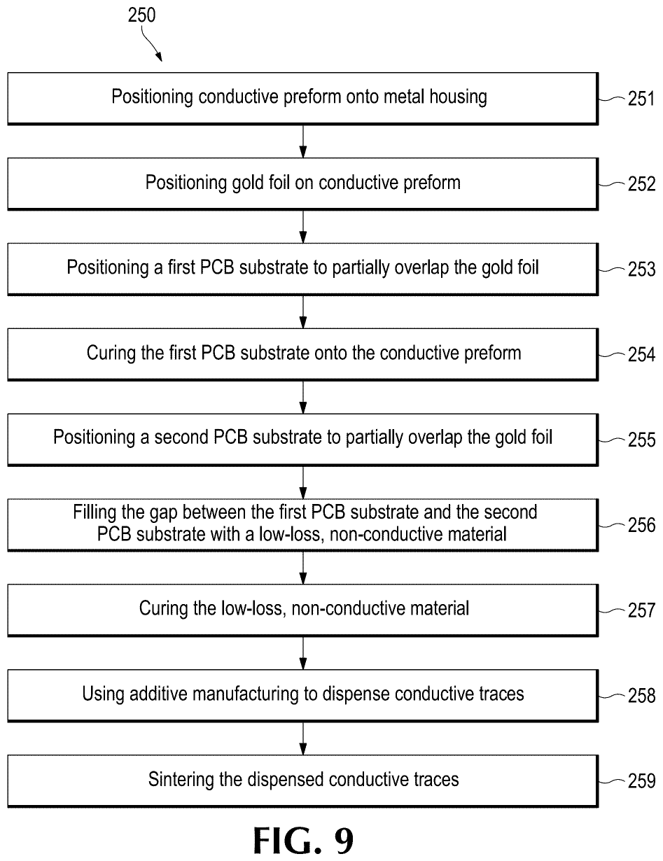

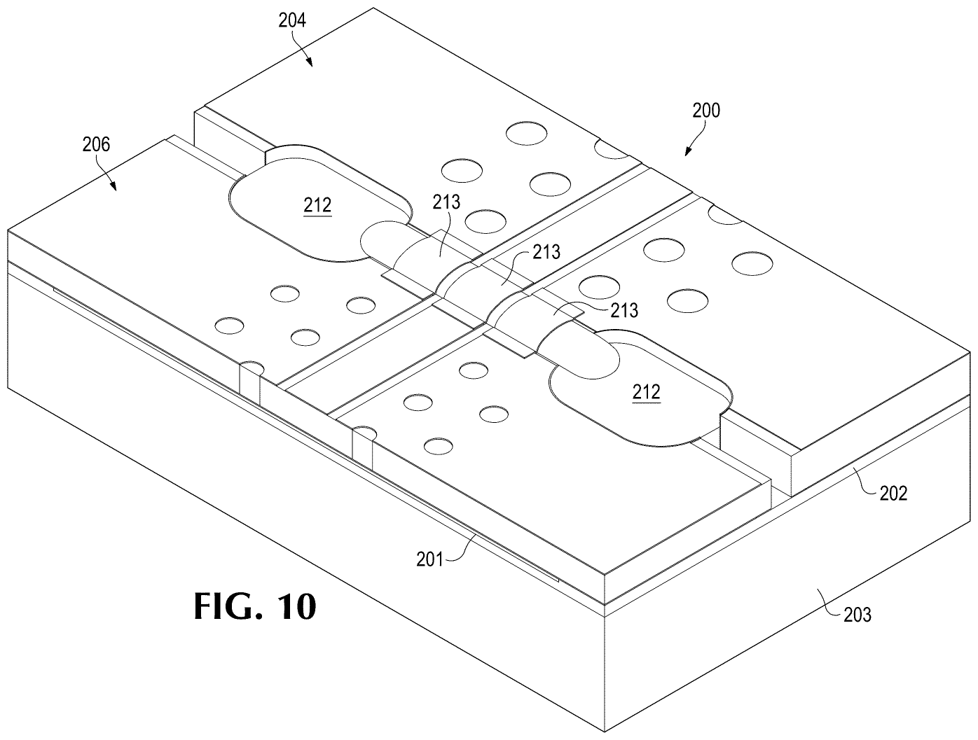

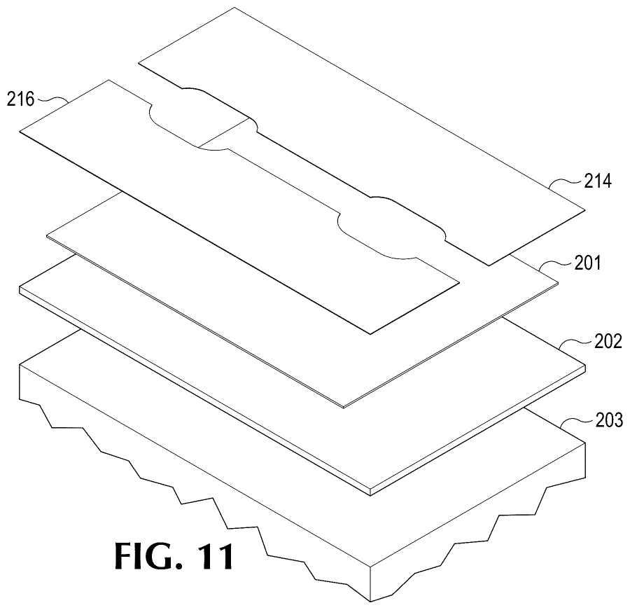

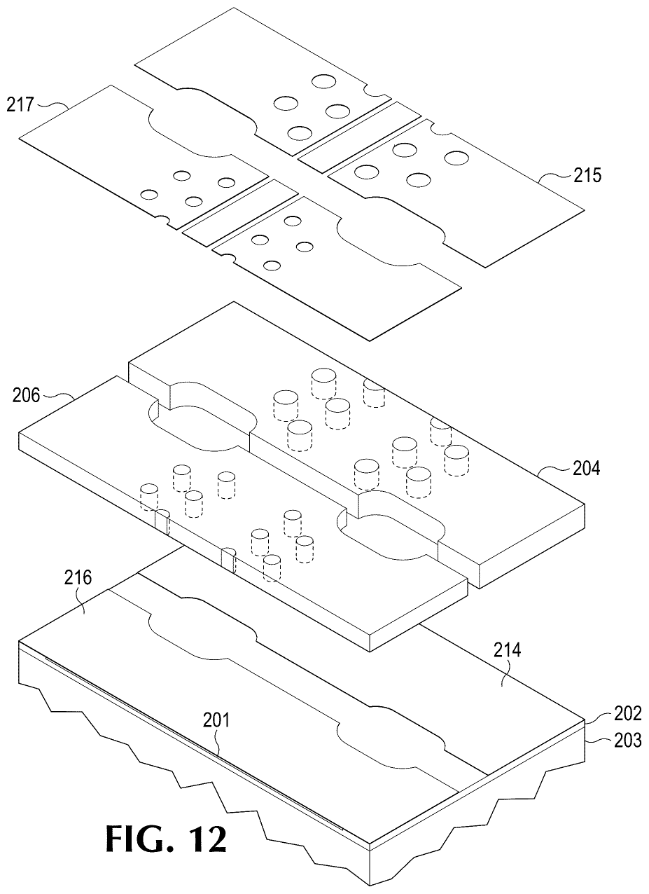

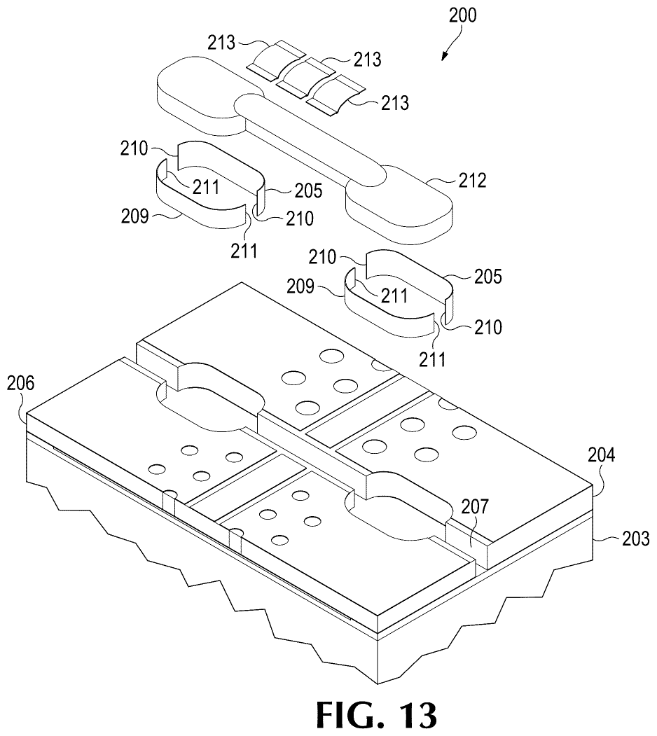

As illustrated in FIGS. 9-14, a method 250 of interconnecting printed-circuit-board (PCB) substrates to provide an interconnected assembly 200 includes positioning 252 gold foil 201 on a conductive preform 202 at a desired location for interconnection. The gold foil 201 may be, for example, 100 mil square by 0.5 mil thick gold sheets. The conductive preform 202 may be, for example, a conductive epoxy preform. In configurations, the method 250 also includes positioning 251 the conductive preform 202 onto a metal housing 203 before positioning gold foil 201 on the conductive preform 202.

The method 250 of interconnecting printed-circuit-board (PCB) substrates also includes positioning 253 a first PCB substrate 204 onto the conductive preform 202 to partially overlap the gold foil 201. The first PCB substrate 204 has an edge-plated cutout 205 at the portion of the first PCB substrate 204 that overlaps the gold foil 201. The term “first PCB substrate” is intended to include the top metallization 215 of the first PCB substrate 204 and the bottom metallization 215 of the first PCB substrate 204, unless otherwise apparent from the context. In configurations, the first PCB substrate 204 is positioned onto the conductive preform 202 by using fiducials on the first PCB substrate 204 and on the metal housing 203 to align the first PCB substrate 204 to the conductive preform 202. Once positioned, the first PCB substrate 204 is cured onto the conductive preform 202. The curing 254 may be, for example, snap (or rapid) curing such as by applying heat through a collet.

The method 250 of interconnecting printed-circuit-board (PCB) substrates also includes positioning 255 a second PCB substrate 206 onto the conductive preform 202 to partially overlap the gold foil 201 while leaving a gap 207 between the first PCB substrate 204 and the second PCB substrate 206. The term “second PCB substrate” is intended to include the top metallization 217 of the second PCB substrate 206 and the bottom metallization 216 of the second PCB substrate 206, unless otherwise apparent from the context. In configurations, edge features of the first PCB substrate 204 are used to properly position the second PCB substrate 206 onto the conductive preform 202. Preferably, the width 208 of the gap 207 between the first PCB substrate 204 and the second PCB substrate 206 is between about 1 mil and about 7 mil. More preferably, the width 208 of the gap 207 is between about 3 mil and about 5 mil. Even more preferably, the width 208 of the gap 207 is about 4 mil.

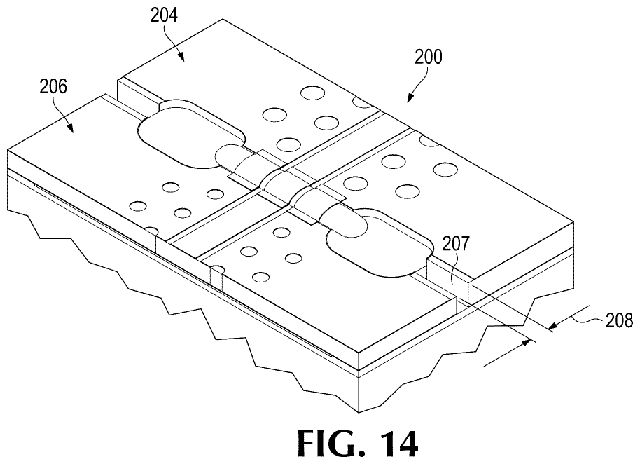

The second PCB substrate 206 has an edge-plated cutout 209 at the portion of the second PCB substrate 206 that overlaps the gold foil 201. When the second PCB substrate 206 is positioned onto the conductive preform 202, the edge-plated cutout 205 of the first PCB substrate 204 is substantially aligned with the edge-plated cutout 209 of the second PCB substrate 206. As used in this context, “substantially aligned” means that the terminating edges 210 of the edge-plated cutout 205 of the first PCB substrate 204 and of the terminating edges 211 of the edge-plated cutout 209 of the second PCB substrate 206 are largely or essentially in line without requiring perfect collinearity, an example of which is illustrated in FIG. 14.

Next, the method 250 of interconnecting printed-circuit-board (PCB) substrates also includes filling 256 the gap 207 between the first PCB substrate 204 and the second PCB substrate 206, the edge-plated cutout 205 of the first PCB substrate 204, and the edge-plated cutout 209 of the second PCB substrate 206 with a low-loss, non-conductive material 212. Once the gap 207 is filled, the dispensed low-loss, non-conductive material 212 is cured 257.

Next, the method 250 of interconnecting printed-circuit-board (PCB) substrates also includes using 258 additive manufacturing to dispense conductive traces 213 at desired locations spanning the gap 207. The conductive traces 213 interconnect the first PCB substrate 204 and the second PCB substrate 206 across the gap 207. In configurations, the additive manufacturing is or includes using aerosol printing to dispense the conductive traces 213. Aerosol printing techniques allow for finer linewidth and gap-width precision. Once dispensed, the method 250 may include sintering 259 the dispensed conductive traces 213 to cure the conductive traces 213 and to improve conductivity of the conductive traces 213.

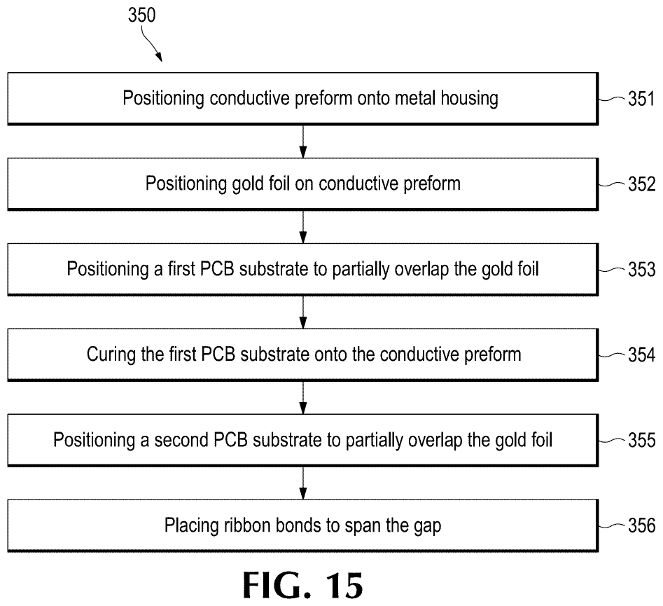

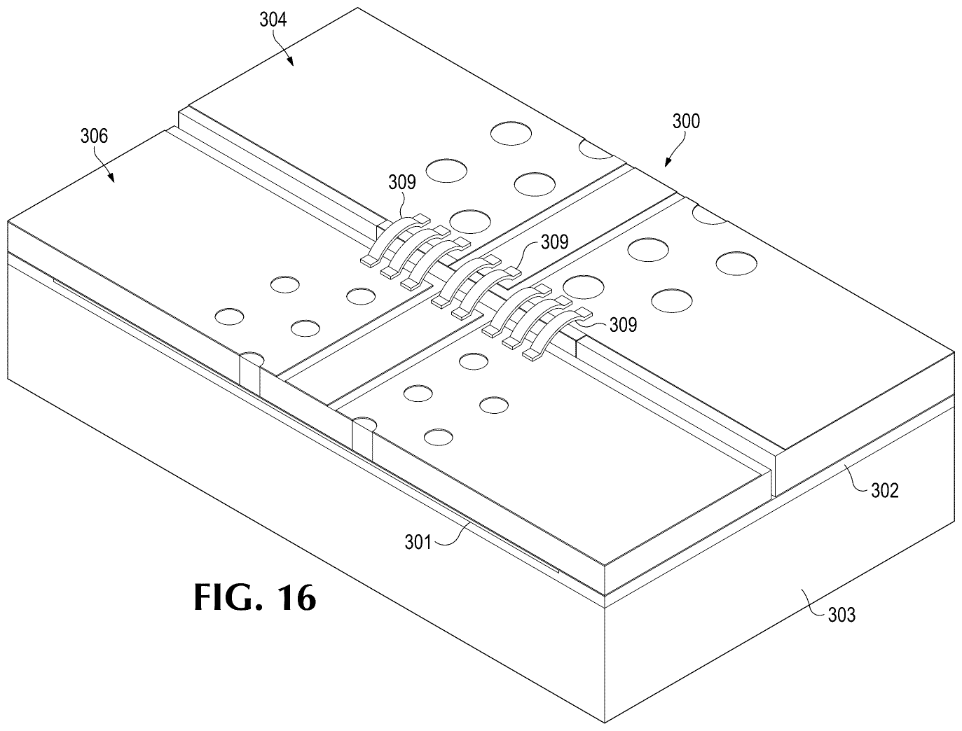

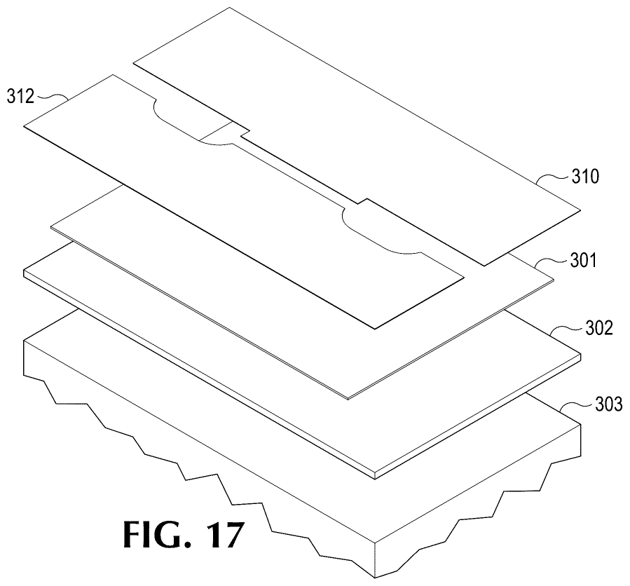

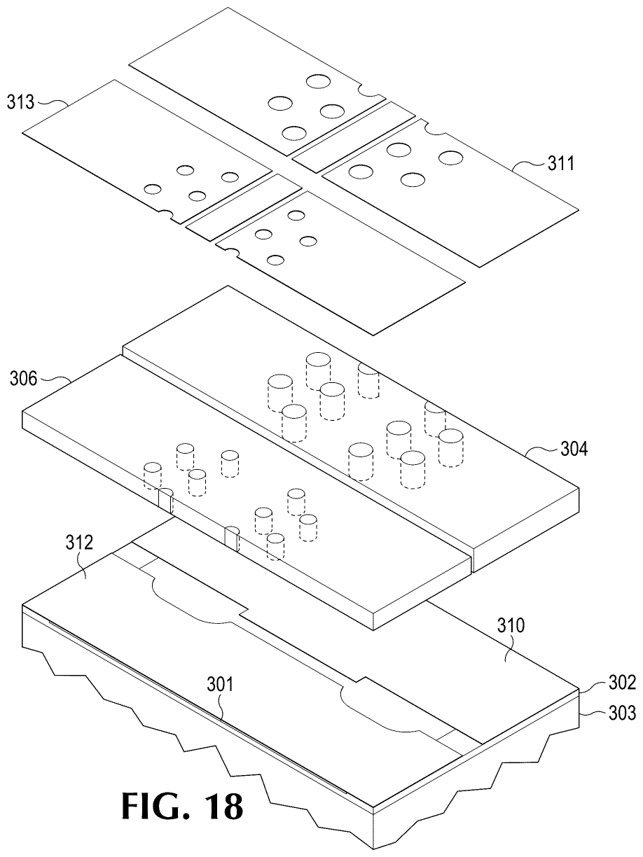

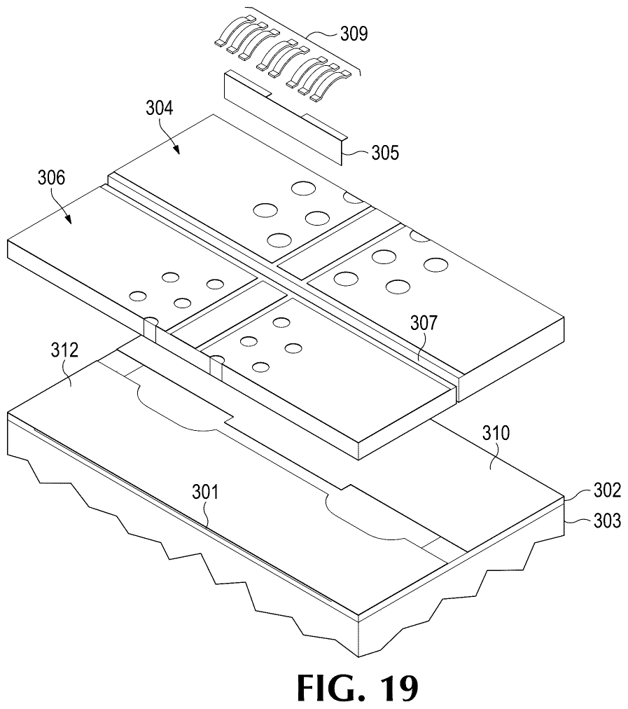

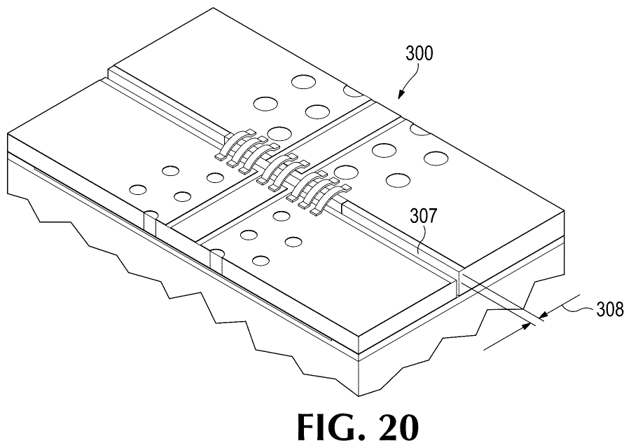

As illustrated in FIGS. 15-20, a method 350 of interconnecting printed-circuit-board (PCB) substrates to provide an interconnected assembly 300 includes positioning 352 gold foil 301 on a conductive preform 302 at a desired location for interconnection. The gold foil 301 may be, for example, 100 mil square by 0.5 mil thick gold sheets. The conductive preform 302 may be, for example, a conductive epoxy preform. In configurations, the method 350 also includes positioning 351 the conductive preform 302 onto a metal housing 303 before positioning gold foil 301 on the conductive preform 302.

The method 350 of interconnecting printed-circuit-board (PCB) substrates also includes positioning 353 a first PCB substrate 304 onto the conductive preform 302 to partially overlap the gold foil 301. The term “first PCB substrate” is intended to include the top metallization 311 of the first PCB substrate 304 and the bottom metallization 310 of the first PCB substrate 304, unless otherwise apparent from the context. The first PCB substrate 304 has edge plating 305 at an edge-plated portion of the first PCB substrate 304, the edge-plated portion being where the first PCB substrate 304 overlaps the gold foil 301. In configurations, the first PCB substrate 304 is positioned onto the conductive preform 302 by using fiducials on the first PCB substrate 304 and on the metal housing 303 to align the first PCB substrate 304 to the conductive preform 302. Once positioned, the first PCB substrate 304 is cured onto the conductive preform 302. The curing 354 may be, for example, snap (or rapid) curing such as by applying heat through a collet.

The method 350 of interconnecting printed-circuit-board (PCB) substrates also includes positioning 355 a second PCB substrate 306 onto the conductive preform 302 to partially overlap the gold foil 301 while leaving a gap 307 between the first PCB substrate 304 and the second PCB substrate 306. Preferably, the width 308 of the gap 307 between the first PCB substrate 304 and the second PCB substrate 306 is between about 0.3 mil and about 2 mil. More preferably, the width 308 of the gap 307 is between about 0.7 mil and about 1.3 mil. Even more preferably, the width 308 of the gap 307 is about 1 mil. The term “second PCB substrate” is intended to include the top metallization 313 of the second PCB substrate 306 and the bottom metallization 312 of the second PCB substrate 306, unless otherwise apparent from the context.

Next, the method 350 of interconnecting printed-circuit-board (PCB) substrates also includes placing 356 ribbon bonds 309 to span the gap 307 at the edge-plated portion of the first PCB substrate 304. The ribbon bonds 309 interconnect the first PCB substrate 304 and the second PCB substrate 306.

Preferably, there is no edge plating 305 on the second PCB substrate 306 where the ribbon bonds 309 interconnect the first PCB substrate 304 and the second PCB substrate 306. More specifically, only one of the two PCB substrates—either the first PCB substrate 304 or the second PCB substrate 306—has edge plating 305 where the ribbon bonds 309 interconnect the first PCB substrate 304 and the second PCB substrate 306.

### EXAMPLES

Illustrative examples of the disclosed technologies are provided below. A particular configuration of the technologies may include one or more, and any combination of, the examples described below.

Example 1 includes a method of interconnecting a printed-circuit-board (PCB) substrate and an integrated-circuit (IC) die, the method comprising: dispensing epoxy into a die cavity of a PCB substrate, the die cavity having full-wrap edge-plating; positioning an IC die in the die cavity and substantially aligning a top surface of the IC die with a top surface of the PCB substrate; curing the dispensed epoxy; substantially filling a gap between the PCB substrate and the IC die with underfill; filling a remaining gap between the PCB substrate and the IC die with non-conductive, aerosol-printed material; curing the underfill and the non-conductive, aerosol-printed material; using additive manufacturing to dispense conductive traces at desired locations spanning the gap and interconnecting the PCB substrate and the IC die; and sintering the dispensed conductive traces.

Example 2 includes the method of any Example 1, further comprising positioning the PCB substrate onto a conductive preform before substantially aligning the top surface of the IC die with the top surface of the PCB substrate.

Example 3 includes the method of Example 2, further comprising positioning the PCB substrate and the conductive preform onto a metal housing before substantially aligning the top surface of the IC die with the top surface of the PCB substrate.

Example 4 includes a method of interconnecting printed-circuit-board (PCB) substrates, the method comprising: positioning gold foil on a conductive preform at a desired location for interconnection; positioning a first PCB substrate onto the conductive preform to partially overlap the gold foil, the first PCB substrate having an edge-plated cutout at a portion of the first PCB substrate overlapping the gold foil; curing the positioned first PCB substrate onto the conductive preform; positioning a second PCB substrate onto the conductive preform to partially overlap the gold foil and leaving a gap between the first PCB substrate and the second PCB substrate, the second PCB substrate having an edge-plated cutout at a portion of the second PCB substrate overlapping the gold foil, the edge-plated cutout of the second PCB substrate being substantially aligned with the edge-plated cutout of the first PCB substrate; filling the gap between the first PCB substrate and the second PCB substrate, the edge-plated cutout of the first PCB substrate, and the edge-plated cutout of the second PCB substrate with a low-loss, non-conductive material; curing the dispensed low-loss, non-conductive material; using additive manufacturing to dispense conductive traces at desired locations spanning the gap and to interconnect the first PCB substrate and the second PCB substrate; and sintering the dispensed conductive traces.

Example 5 includes the method of Example 4, further comprising positioning the conductive preform onto a metal housing before positioning gold foil on the conductive preform.

Example 6 includes the method of any of Examples 4-5, in which using additive manufacturing to dispense conductive traces comprises using aerosol printing to dispense the conductive traces.

Example 7 includes a method of interconnecting printed-circuit-board (PCB) substrates, the method comprising: positioning gold foil on a conductive preform at a desired location for interconnection; positioning a first PCB substrate onto the conductive preform to partially overlap the gold foil, the first PCB substrate having edge plating at an edge-plated portion of the first PCB substrate; curing the positioned first PCB substrate onto the conductive preform; positioning a second PCB substrate onto the conductive preform to partially overlap the gold foil and leaving a gap between the first PCB substrate and the second PCB substrate; and placing ribbon bonds spanning the gap at the edge-plated portion of the first PCB substrate and interconnecting the first PCB substrate and the second PCB substrate.

Example 8 includes the method of Example 7, further comprising positioning the conductive preform onto a metal housing before positioning gold foil on the conductive preform.

Aspects may operate on a particularly created hardware, on firmware, digital signal processors, or on a specially programmed general purpose computer including a processor operating according to programmed instructions. The terms “controller” or “processor” as used herein are intended to include microprocessors, microcomputers, ASICs, and dedicated hardware controllers. One or more aspects may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, RAM, etc. As will be appreciated by one of skill in the art, the functionality of the program modules may be combined or distributed as desired in various configurations. In addition, the functionality may be embodied in whole or in part in firmware or hardware equivalents such as integrated circuits, field programmable gate arrays (FPGA), and the like. Particular data structures may be used to more effectively implement one or more aspects of the disclosed systems and methods, and such data structures are contemplated within the scope of computer executable instructions and computer-usable data described herein.

The contents of the present document have been presented for purposes of illustration and description, but such contents are not intended to be exhaustive or limited to the disclosure in the form disclosed. Many modifications and variations will be apparent to those of ordinary skill in the art without departing from the scope and spirit of the disclosure. The aspects of the disclosure in this document were chosen and described to explain the principles of the disclosure and the practical application, and to enable others of ordinary skill in the art to understand the disclosure with various modifications as are suited to the particular use contemplated.

Accordingly, it is to be understood that the disclosure in this specification includes all possible combinations of the particular features referred to in this specification. For example, where a particular feature is disclosed in the context of a particular example configuration, that feature can also be used, to the extent possible, in the context of other example configurations.

Additionally, the described versions of the disclosed subject matter have many advantages that were either described or would be apparent to a person of ordinary skill. Even so, all of these advantages or features are not required in all versions of the disclosed apparatus, systems, or methods.

Also, when reference is made in this application to a method having two or more defined steps or operations, the defined steps or operations can be carried out in any order or simultaneously, unless the context excludes those possibilities.

The terminology used in this specification is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises” or “comprising,” when used in this specification, specify the presence of stated features, integers, steps, operations, elements, or components, but do not preclude the presence or addition of one or more other features, integers, steps, operations, elements, components, or groups thereof. Hence, for example, an article “comprising” or “which comprises” components A, B, and C can contain only components A, B, and C, or it can contain components A, B, and C along with one or more other components.

Also, directions such as “vertical,” “horizontal,” “right,” and “left” are used for convenience and in reference to the views provided in figures. But the apparatus may have a number of orientations in actual use. Thus, a feature that is vertical, horizontal, to the right, or to the left in the figures may not have that same orientation or direction in actual use.

It is understood that the present subject matter may be embodied in many different forms and should not be construed as being limited to the example configurations set forth in this specification. Rather, these example configurations are provided so that this subject matter will be thorough and complete and will convey the disclosure to those skilled in the art. Indeed, the subject matter is intended to cover alternatives, modifications, and equivalents of these example configurations, which are included within the scope and spirit of the subject matter set forth in this disclosure. Furthermore, in the detailed description of the present subject matter, specific details are set forth to provide a thorough understanding of the present subject matter. It will be clear to those of ordinary skill in the art, however, that the present subject matter may be practiced without such specific details.

I (or we) claim:

1. A method of interconnecting a printed-circuit-board (PCB) substrate and an integrated-circuit (IC) die, the method comprising:
dispensing epoxy into a die cavity of a PCB substrate, the die cavity having full-wrap edge-plating;
positioning an IC die in the die cavity and substantially aligning a top surface of the IC die with a top surface of the PCB substrate;
curing the dispensed epoxy;
substantially filling a gap between the PCB substrate and the IC die with underfill;
filling a remaining gap between the PCB substrate and the IC die with non-conductive, aerosol-printed material;
curing the underfill and the non-conductive, aerosol-printed material;
using additive manufacturing to dispense conductive traces at desired locations spanning the gap and interconnecting the PCB substrate and the IC die; and
sintering the dispensed conductive traces.

2. The method of claim 1, further comprising positioning the PCB substrate onto a conductive preform before substantially aligning the top surface of the IC die with the top surface of the PCB substrate.

3. The method of claim 2, further comprising positioning the PCB substrate and the conductive preform onto a metal housing before substantially aligning the top surface of the IC die with the top surface of the PCB substrate.

4. A method of interconnecting printed-circuit-board (PCB) substrates, the method comprising:
positioning gold foil on a conductive preform at a desired location for interconnection;
positioning a first PCB substrate onto the conductive preform to partially overlap the gold foil, the first PCB substrate having an edge-plated cutout at a portion of the first PCB substrate overlapping the gold foil;
curing the positioned first PCB substrate onto the conductive preform;
positioning a second PCB substrate onto the conductive preform to partially overlap the gold foil and leaving a gap between the first PCB substrate and the second PCB substrate, the second PCB substrate having an edge-plated cutout at a portion of the second PCB substrate overlapping the gold foil, the edge-plated cutout of the second PCB substrate being substantially aligned with the edge-plated cutout of the first PCB substrate;
filling the gap between the first PCB substrate and the second PCB substrate, the edge-plated cutout of the first PCB substrate, and the edge-plated cutout of the second PCB substrate with a low-loss, non-conductive material;
curing the dispensed low-loss, non-conductive material;
using additive manufacturing to dispense conductive traces at desired locations spanning the gap and to interconnect the first PCB substrate and the second PCB substrate; and
sintering the dispensed conductive traces.

5. The method of claim 4, further comprising positioning the conductive preform onto a metal housing before positioning gold foil on the conductive preform.

6. The method of claim 4, in which using additive manufacturing to dispense conductive traces comprises using aerosol printing to dispense the conductive traces.

7. A method of interconnecting printed-circuit-board (PCB) substrates, the method comprising:
positioning gold foil on a conductive preform at a desired location for interconnection;
positioning a first PCB substrate onto the conductive preform to partially overlap the gold foil, the first PCB substrate having edge plating at an edge-plated portion of the first PCB substrate;
curing the positioned first PCB substrate onto the conductive preform;
positioning a second PCB substrate onto the conductive preform to partially overlap the gold foil and leaving a gap between the first PCB substrate and the second PCB substrate; and
placing ribbon bonds spanning the gap at the edge-plated portion of the first PCB substrate and interconnecting the first PCB substrate and the second PCB substrate.

8. The method of claim 7, further comprising positioning the conductive preform onto a metal housing before positioning gold foil on the conductive preform.
